(19) United States
(12) Patent Application Publication
(10) Pub. No.: US 2011/0100423 A1
(43) Pub. Date: May 5, 2011

(54) Light Scattering and Transport for Photosensitive Devices

(75) Inventor: Charles M. Fortmann, Bellport, NY (US)

(73) Assignee: The Research Foundation of State University of New York, Albany, NY (US)

(21) Appl. No.: 12/915,958

(22) Filed: Oct. 29, 2010

Related U.S. Application Data
(60) Provisional application No. 61/256,477, filed on Oct. 30, 2009.
(60) Provisional application No. 61/308,639, filed on Feb. 26, 2010.

(51) Int. Cl. H01L 31/052; G02B 5/02; G02F 1/35; B05D 5/12; B32B 37/16; H05K 13/00

(52) U.S. Cl. 136/246; 359/599; 359/327; 427/74; 156/278; 156/279; 29/592.1

(57) ABSTRACT

Apparatus and methods are described for efficiently transporting and using incident radiation falling on photosensitive devices and structures supporting photosensitive devices. For example, an apparatus includes a low-absorption medium capable of passing and absorbing incident radiation; a scattering material disposed over at least a portion of or within the low-absorption material, the scattering material permitting a portion of incident light to pass therethrough; and a reflective surface disposed adjacent to the low-absorption medium to reflect radiation towards or within the medium.

### CROSS-REFERENCE TO RELATED APPLICATIONS

This Application claims the benefit of U.S. Patent Application No. 61/256,477, filed Oct. 30, 2009 and titled “Apparatus and Method to Optimize Solar Cell Optics, Use and Durability” and U.S. Patent Application No. 61/308,639, filed Feb. 26, 2010 and titled “Light Scattering and Transport for Photosensitive Devices,” the entire contents of which are hereby incorporated herein by reference.

### TECHNICAL FIELD

The description relates to light scattering and transport for photosensitive devices including photovoltaic devices, thermal photovoltaic devices, and solar cells.

### BACKGROUND

The devices, cells, panels, modules, and methods described arise from the desire to more efficiently transport and use incident radiation and light falling on photosensitive devices and structures supporting photosensitive devices.

### SUMMARY

The concepts described herein relate to the efficient transport and use of incident radiation falling on photosensitive devices and structures supporting photosensitive devices.

Some embodiments feature a structure or apparatus that efficiently transports light or other radiation (e.g., infrared) from a larger-than-photosensitive-device area to a relatively small-area photosensitive device. Thus, it becomes possible to use relatively small-area photosensitive devices, spaced apart from each other in a panel or module, to achieve about the same overall energy generation as a panel or module mostly or completely covered by large-area photosensitive devices. For example, photosensitive devices operating under a relatively mild concentration (e.g., covering about 50% of the panel or module surface area) can be electrically connected (e.g., disposed in electrical communication or strung together). Light-conveying structures, as described herein, can then be placed or disposed between the photosensitive devices, resulting in fewer photosensitive devices per unit area than previously developed. Cost savings are realized by covering only a portion of the available panel or module surface with photosensitive devices, which are typically more expensive than the conveying structure to manufacture. Additionally, since the structure can be made of flexible materials, even rigid photosensitive devices can be fabricated into flexible panels or modules due to a flexible, hinge-like, light-conveying structure positioned between the relatively inflexible photosensitive devices.

A benefit realized from using the apparatus or structures is facilitating development and use of small-area solar cells fabricated from low-cost primary source materials. For example, small-size samples generally involve specifically-designed junction and surface passivation techniques to avoid contamination of the power generating regions of the small-area solar cells. Low-temperature amorphous silicon surface passivation of single crystal silicon spheres, point contacting, flash diffusion for ohmic contacts, industrial silicon fabrication facilities to engineer automated processes, and channel glass-based showerheads to extrude silicon spheres can be used and enable the inexpensive manufacture of small-area silicon solar cells.

In some embodiments, the apparatus or structures can facilitate a single crystal silicon approach to flexible high performance photovoltaic modules. Successful approaches involve overcoming flexibility and weight limitations to attain mobile, self-contained, flexible photovoltaic panels or modules. The apparatus and structures provide a lightweight light-collection device that attains low panel weight, flexibility, and damage-resistance by using a bubble-wrap-like medium or material around each solar cell that provides light collection for high-aperture-area efficiency. A series of small-area crystal silicon solar cells can achieve approximately the same efficiency as a rigid panel having about the same surface area as the aggregate of the series of small-area cells. These panels are small enough to withstand significant force and stress, and provide flexibility and low weight. Also, small solar cell size enables small regions or areas of cells to be wired or connected together (or allowed to electrically communicate) into portions of panels or modules, each achieving the overall panel or module voltage. Thus, large area panels can be formed of parallel-connected regions. Damage to one or several regions reduces the overall current and power proportionally to the area damaged, however, the overall voltage is not significantly affected.

In some applications that use thermal photovoltaic cells (e.g., narrow-band-gap, solar-cell-like photovoltaic cells for use with heat sources (e.g., infrared radiation)), the apparatus and structures can include a device to transport and broaden the available illumination spectrum. For example, some embodiments feature a Raman scattering material or media, which can be any low-absorption material or media (e.g., material or media that are substantially transparent for a broad spectrum of radiation or material or media that are substantially transparent for radiation in a spectral region, such as infrared or visible light, that is of importance to a particular application) that strongly Raman scatters radiation. Raman scattering materials can include, for example, silicon, quartz, glass or diamond particles.

Substantially transparent, spectrum-altering materials, such as Raman scattering and/or shift materials made of small-sized particles, can increase the spectral modification of incident radiation. For example, in embodiments featuring narrow-gap photovoltaic cells (e.g., cells with an absorber band gap less than about 1.0 electron volt (eV)), silicon particles can be used within or about the light path for spectrum modification, as silicon strongly Raman shifts light while not absorbing light with energy less than about 1.0 eV. The use of Raman-scattering materials increases the effective path length over which light having a wavelength less than the band-gap for silicon can pass before being absorbed. Increasing the light path length or time light spends traveling within materials that modify the incident spectrum can increase the occurrence of spectral modification.

In general, in one aspect, there is an apparatus. The apparatus includes a low-absorption medium capable of passing and absorbing incident radiation (e.g., radiation with the visible, near-infrared or infrared frequency bands). The apparatus includes a scattering material disposed over at least a portion of or within the low-absorption material, and the scattering material permits a portion of incident light to pass therethrough (e.g., to the low-absorption medium). The apparatus also includes a reflective surface disposed adjacent the low-absorption medium to reflect radiation towards or within the medium.

In some embodiments, the scattering material includes at least one of a polymer-based material, a crystalline or polycrystalline material, a structured surface, a granular organic material, a granular inorganic material, or any combination of these materials. The polymer-based material can include, for example, titanium oxide, titanium dioxide, zinc oxide, cadmium sulfide, glass particles, plastic-based particles, or any combination of these. The low-absorption medium can include at least one of air, a polymer material (or polymer-based material), a glass material, quartz (or other silicate materials), diamond (or other organic materials), water-based materials, or a combination of these. The low-absorption medium can also include a material that is substantially transparent to radiation within a range of operation of an optically-coupled photosensitive device within or on the apparatus. For example, when the photosensitive device is a thermal photovoltaic cell responsive to infrared radiation, the low-absorption medium can be, for example, a silicon material since silicon is effectively transparent to radiation within the infrared band of the electromagnetic spectrum.

The low-absorption medium can define an array or arrangement of sites at which photosensitive or photovoltaic devices are located as well as spaces between the sites. These sites are sometimes referred to as “solar cell sites.” Some embodiments feature a spectral-conversion structure or material that facilitates a Stokes-type or anti-Stokes-type modification (e.g., up-conversion or down-conversion) of incident radiation in or on the medium. For example, the spectral-conversion structure can include a substantially-transparent matrix that has particles embedded therein. The matrix defines a first refractive index, and the particles include at least one of a luminescent material, a silicon material, a Raman-shifting particle, or any combination thereof.

Some embodiments featuring a spectral-conversion structure also feature a thermal photovoltaic solar cell. The thermal photovoltaic solar cell can be supported on the scattering material to permit incident light to be either absorbed in the thermal photovoltaic solar cell or passed to the spectral-conversion structure for modification and subsequent absorption (by the medium, other photosensitive devices or other thermal photovoltaic solar cells). Generally, the apparatus can include a photosensitive device or photovoltaic device disposed within or over the medium. Applicable photosensitive devices include silicon-based solar cells, and photovoltaic devices include (but are not limited to) thermal photovoltaic cells.

Some applications involve tailoring or configuring the appearance of the apparatus (e.g., to minimize visual or thermal detection). The scattering material can be configured to achieve particular application objectives. For example, the scattering material can include a first layer that includes titanium oxide, a second layer that includes titanium oxide, and an intermediate layer that includes a dye material disposed between the first and second layers. The arrangement or configuration of the dye material can, for example, be designed and constructed to promote application objectives. The reflective surface of the apparatus can include at least one of a metallic material, a dielectric coating, a mirror, a half-wavelength coating, or a combination of these. The reflective surface includes, in some implementations, a reflection-enhancing material or coating.

In general, in another aspect, there is a solar cell module that includes a flexible base having a plurality of photosensitive devices mounted thereto or thereon. The flexible base includes a low-absorption medium disposed at least between the plurality of photosensitive devices, and the medium permits radiation to pass to the plurality of photosensitive devices. At least one photosensitive device is in electrical communication with at least one other photosensitive device of the plurality of photosensitive devices. The module also includes a scattering material disposed over the flexible base that permits a portion of incident radiation to pass therethrough to the plurality of photosensitive devices and the medium.

The scattering material, in some embodiments, selectively rejects a portion of incident infrared radiation from passing to the plurality of photosensitive devices and the medium. The scattering material can be a coating or layer. At least one flexible interconnection can be employed to facilitate electrical communication between the photosensitive devices of the plurality of photosensitive devices. In some applications, an electrical connection facilitates electrical communication between the module and a second module containing a second set of photosensitive devices. The module can include a first region that is associated with a first function (e.g., power generation) and a second region associated with a second function (e.g., code generation). For such implementations, a condition in the first region of the module that affects the first function does not affect achievement of the second function. In this way, failures within the module can be isolated.

In general, in another aspect, there is an apparatus. The apparatus includes a medium for transmitting or absorbing incident radiation. The apparatus includes a spectral-modification material disposed over or within the medium. The apparatus includes a reflective surface disposed adjacent the medium to reflect incident radiation towards or within the medium. The apparatus includes a scattering material disposed between a portion of or within the material and the reflective surface. The apparatus also includes a photosensitive device in optical communication with the medium. Additionally, the apparatus includes a thermal regulation unit system in thermal communication with the medium, the photosensitive device, or both.

In some embodiments, the thermal regulation unit system is configured to maintain the medium for transmitting or absorbing incident radiation, the spectral-modification material, the photosensitive device, or any combination of these at specified temperatures, which can differ depending on the layer, material, or medium, as desired, for increased energy conversion efficiency.

In general, in another aspect, there is an apparatus. The apparatus includes a spectral-modification material including a reflective surface and adjacent to a low-absorption medium for passing or absorbing incident radiation, the reflective surface focusing radiation towards or within the spectral-modification material and the medium. The apparatus also includes one or more photosensitive devices over or within the medium. Additionally, the apparatus includes a thermal regulation system in thermal communication with the spectral-modification media.

In still another aspect, there is a method (e.g., a method for manufacturing an apparatus). The method involves selecting a first parameter associated with absorption of incident light and forming a flexible base that includes a plurality of sites each for mounting a photosensitive device and a medium disposed between the plurality of sites. The size of the spaces between the sites is determined based on the selected first parameter. The method involves forming a scattering layer based in part on a second parameter associated with scattering of incident radiation and disposing the scattering layer over the flexible base.

The method can also involve positioning (or forming) a reflective surface of a film adjacent the flexible base. The film can include depositing particles of a light-reflective material within a polymer film. In some embodiments, forming the scattering layer involves depositing titanium oxide particles within or on a polymer film. Forming the scattering layer can, in some implementations, forming a first layer containing titanium oxide particles, forming a second layer containing titanium oxide particles and disposing an intermediate, dye-based layer between the first and second layers.

In some embodiments, the method involves locating (or positioning or placing) at least one photosensitive device at a site of the plurality of sites. The method can involve locating (or positioning or placing) a second photosensitive device at a second site of the plurality of sites and connecting the photosensitive device and the second photosensitive device to facilitate electrical communication.

The method can also involve forming a spectral-modification structure. The spectral modification structure is formed by forming a substantially transparent matrix having a first refractive index and embedding at least one of a luminescent material, a silicon material, a Raman-shifting material, or any combination of these within the matrix. The spectral modification structure is then disposed on or within the medium. In some embodiments, the method involves positioning the substantially transparent matrix relative to a silicon-based substrate having a second refractive index substantially different than the first refractive index. The method can also involve locating (or positioning or placing) at least one thermal photovoltaic cell at a site of the plurality of sites.

These and other features will be more fully understood by reference to the following description and drawings, which are illustrative and not necessarily to scale.

### BRIEF DESCRIPTION OF THE DRAWINGS

FIG. 1 depicts a cross-sectional view of a structure or device that includes a layer of scattering material, a layer of low-absorption medium, a photosensitive device, and a reflective surface.

FIG. 2A depicts a portion of a photosensitive device panel or module illustrating electrical interconnection and/or intercommunication between photosensitive devices on the module or panel.

FIG. 2B depicts a photosensitive device panel including the portion of a photosensitive device panel or module of in electrical communication with other portions of panel or module and electrical interconnections between the portions of panels or modules.

FIG. 3A depicts a cross-sectional view of a panel or module in a flexed arrangement.

FIG. 3B depicts a photosensitive device panel or module and illustrates the panel's or module's folding axes.

FIG. 4 depicts a cross-sectional view of a structure or device that includes a layer of scattering material, a thermal photovoltaic solar cell over the layer of scattering material, a layer of low-absorption medium, a reflective surface, and a spectral-modification structure within the layer of low-absorption medium.

FIG. 5 depicts a cross-sectional view of a structure or device that includes a layer of scattering material, a layer of low-absorption medium having a smooth surface, a reflective surface, photovoltaic cells and a thermal regulation unit.

FIG. 6 depicts a cross-sectional view of a structure or device that includes a photovoltaic cell, a layer of low-absorption medium, Raman-scattering material or media, a reflective surface, and a thermal regulation unit.

FIG. 7 depicts a cross-sectional view of a structure or device that includes a photovoltaic cell, a first reflective surface, a layer of low-absorption medium, a Raman-scattering material or media, a second reflective surface, a thermal regulation unit, and a thermal conduit.

FIG. 8 depicts a cross-sectional view of a structure or device that includes a layer of scattering material containing small-grained materials or media, a layer of low-absorption medium, a reflective surface, and a photosensitive device.

FIG. 9 is a flow chart that depicts a method of assembling a panel or module described herein.

### DETAILED DESCRIPTION

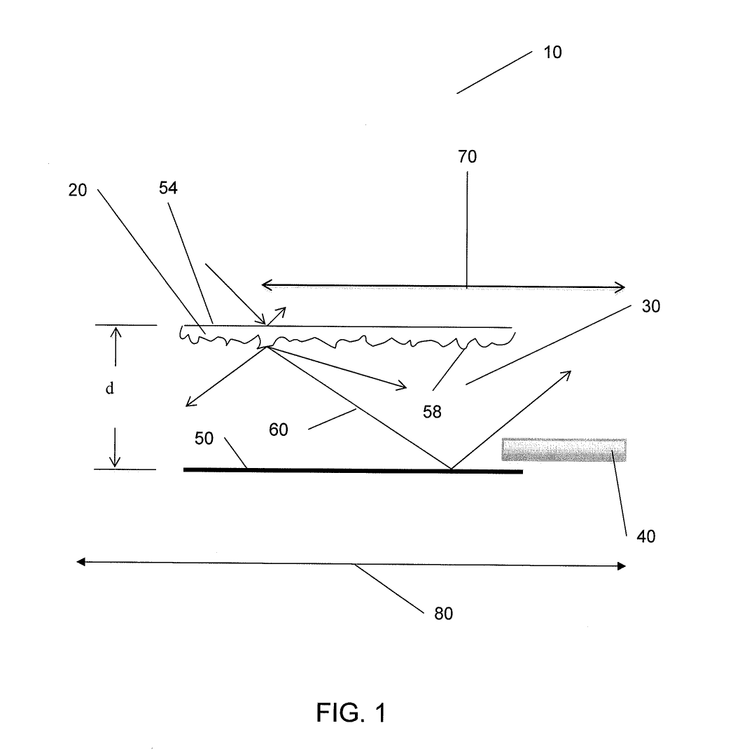

Referring to the drawings, FIG. 1 depicts a cross-sectional view of a structure or device 10 that includes a layer 20 of scattering material, a layer 30 of low-absorption medium, a photosensitive device 40, and a reflective surface 50. In the structure 10, for example, the layer 20 of scattering material functions to scatter and/or transmit incident light or radiation into and through the layer 30 of low-absorption medium. Within the layer 30 of low-absorption medium, light moves laterally (e.g., back or forth along the axis indicated by line 80) via scattering and reflections at or with the reflective surface 50. The photosensitive device 40 absorbs and converts the incident light energy into electricity.

The layer 20 of scattering material can include polymer-based materials, a crystalline or polycrystalline material, a structured surface, a granular organic material, a granular inorganic material, or any combination of these. A polymer-based material can include, for example, titanium oxide, titanium dioxide, zinc oxide, cadmium sulfide, glass particles, plastic-based particles, or any combination of these. In other embodiments, the layer 20 of scattering material is a coating in or on the layer 30 of low-absorption medium, such as a titanium dioxide (TiO₂)-based coating. The coating can be deposited using any number of techniques, including, for example, screen printing, spraying, or vacuum deposition.

The layer 30 of low-absorption medium can include any material substantially transparent to some or all radiation. Examples of low-absorption media can include air, a polymer material, a glass material, a water-based material, quartz, diamond, or any combination of these. In some embodiments, the layer 30 of low-absorption medium is substantially transparent to radiation within a range of operation of the photosensitive device 40. For example, if the incident radiation is infrared, the layer 30 of low-absorption medium can permit permeability of the infrared radiation while not necessarily allowing permeation of other types of radiation (e.g., visible light). In some embodiments, the layer 30 of low-absorption medium is selected so as to reject a portion of incident radiation from passing through it or selectively reject incident radiation.

In some embodiments, the photosensitive device 40 can be any available photosensitive device. The photosensitive device 40 can be one or more high-efficiency, single-crystal solar cells. For example, the photosensitive device 40 can be one or more silicon solar cells having approximately 20% efficiency, where the efficiency indicates the percentage of energy from incident radiation converted into electrical energy. In one implementation, one or more commercially-available, dopant-infused solar cells can be cut into smaller sizes (e.g., squares approximately 1 mm along each side) using commercially-available programmable-laser cutting stations to produce a higher number of smaller-sized solar cells. These smaller-sized solar cells can be electrically connected using available wire bonding equipment. Such large-area, high-efficiency solar cells from which to form a particular photosensitive device 40 are commercially-available from various sources, such as SunPower® Corporation of San Jose, Calif., Sharp® Corporation of Osaka, Japan, Kyocera® Corporation of Kyoto, Japan, or Kyocera® Solar, Inc. of Scottsdale, Ariz.

In some embodiments, the photosensitive device 40 is a silicon solar cell fabricated from high-purity silicon powders. A wire-bonding dopant diffusion step allows controllable attachment via bonding pads to silicon-based or silicon-alloy materials facilitating ohmic contact with the cell. In some embodiments, fabricating solar cells includes depositing amorphous silicon and/or silicon-alloys onto small-crystal silicon or silicon-alloy solar cells for, e.g., low-temperature surface passivation and/or anti-reflection coating properties.

The reflective surface 50 can include effectively any reflective material. For example, the reflective surface 50 can be made of a metallic material, a dielectric coating, a mirror, a half-wavelength coating, or any combination of these. The reflective surface 50 also can include a reflection-enhancing material or coating. The reflective surface 50 can be fabricated using any number of techniques, including, for example, by sputtering silver or aluminum or vacuum evaporation of silver or aluminum.

In some applications, the layer 20 of scattering material and the reflective surface 50 can be formed from polymer films. In such embodiments, the polymer films can form the basis of a light conveyance structure, panel, or module. For example, TiO₂-based coatings and/or mirror-like metallic coatings can be applied to the layer 30 of low-absorption medium. In an implementation, TiO₂-based coatings are applied to the light-incident side 54 of the layer 30 of low-absorption medium and mirror-like metallic coatings are applied to the other side 58 of the layer 30 of low-absorption medium. Disposing photonic-engineered TiO₂/polymer structures between individual photosensitive devices, or photosensitive device sites, increases light collection and, correspondingly, reduces cost by reducing the amount of area devoted to photosensitive devices. The films also protect the photosensitive devices, interconnects, and electrical contacts from the environment and provide a high degree of flexibility to the module.

In some implementations, the structure 10 can be manufactured from flexible, inexpensive, polymer or polymer-based materials, such as Mylar®. For example, the layer 20 of scattering material can be made from TiO₂-coated Mylar®. The layer 30 of low-absorption medium can be a substantially-transparent medium such as Mylar®. The reflective surface 50 can be made from mirror-like, metallic-coated Mylar®.

Additional beneficial aspects of the apparatus, structures (e.g., panels or modules), or devices can be further illustrated with the following brief discussion of their theoretical underpinnings.

Light conveyance can be approached from several perspectives. For example, using a ray-tracing approach, diffusive Lambertian reflectors have been among the best rear-reflector systems for solar cell applications. However, ray-tracing, while accurate, can become complicated in diffusive media (e.g., when scattering statistics and probability factor in).

Another approach to light conveyance theory considers light propagation in a dispersive medium as a form of Brownian motion in which light scatters randomly within the medium until the light is absorbed (e.g., either by the medium or by impurities or devices within the medium). In general, there is no absolute maximum value for how far light will travel in an absorptive medium; however, a measurable distance can be approximated by the quantity 1/α, where α is the absorption coefficient of the medium. According to Beer's law, after light has traveled a distance of 1/α, approximately 30% of the light is absorbed and approximately 70% of the incident light remains unabsorbed.

In some circumstances, it is useful to describe light propagation in terms of diffusion theory. In such circumstances, diffusion coefficients can be defined and used to determine the distance particles (e.g., photons of light) move in a particular time period. Following particle-system practice, the diffusion coefficient, D, is generally defined in terms of a hop rate, Γ, and a hop distance, λₕₒₚ, as set forth in Equation 1:

$$D = \frac{1}{6} {Γλ}_{hop}^{2} . \qquad ( 1 )$$

Like particle systems, the photon hop length represents the distance between light-scattering events in a medium. Unlike particle systems, the hop rate for photons is directly related to the hop distance since photons do not exist in a stationary state. Therefore, for photons, the hop rate Γ and the diffusion coefficient D can be written as follows in Equation 2:

$$Γ = \frac{1}{{t}_{0}} = \frac{1}{( \frac{{λ}_{hop}}{c / N} )} = \frac{c}{N {λ}_{hop}} ∴ D = \frac{1}{6} \frac{c {λ}_{hop}}{N} . \qquad ( 2 )$$

The determination of the amount of light that diffuses to a particular point and/or plane in a given system involves setting-up and solving a Laplace equation. The Laplace equation appropriate for a structure illuminated with a photon flux of G is written below as Equation 3.

$$D {∇}^{2} n + G - \frac{n}{τ} \qquad ( 3 )$$

where, α_{λ} is a nominal absorption coefficient of the medium as a function of photon wavelength (or wavelength of incident radiation);
λ is the photon wavelength;
τ is the lifetime of a nominal photon;
c/N is the speed of light traveling in a medium having an index of refraction of N.
The time τ of a nominal photon is related to the nominal distance traveled by the photon in a medium before the photon is absorbed, which, in turn is roughly equal to the reciprocal of the absorption coefficient, α_{λ} in the small absorption limit (e.g., 1/α). The small-absorption limit is generally an appropriate approximation for photon transport in the low-absorption light transport structures described herein.

Equation 3 can be optimized for light collection and/or light transport. The nominal diffusion length, l is represented in Equation 4. Most photons within the nominal diffusion length will be collected by the solar cells within an apparatus. The nominal diffusion length is analogous to the diffusion length in particle cases and its behavior is governed by Equation 4:

$$𝓁 = \sqrt{D τ} {\to }_{τ ∼ \frac{N}{c α}} \sqrt{\frac{DN}{c α}} = \sqrt{\frac{( \frac{1}{6} \frac{c {λ}_{hop}}{N} ) N}{c α}} = \sqrt{\frac{1}{6} \frac{{λ}_{hop}}{α}} \qquad ( 4 )$$

One of the parameters that affects power generated by photosensitive devices 40 in an apparatus or structure 10 involves the distance 70 between scattering events and the amount of light absorbed in the layer 30 of low-absorption medium. More specifically, maximizing the distance 70 between light scattering events while minimizing absorption by the medium leads to more light collected by photosensitive devices 40 and/or more power generated. A benefit of the apparatus, structures, or devices is that these parameters or conditions can be met with a low-cost, composite system in which the light scattering event and the travel between scattering events occurs in two different materials. Each material can be optimized for a particular purpose (e.g., maximizing scattering or minimizing absorption).

Returning to FIG. 1, light 60 travels through or within the layer 30 of low-absorption medium after being scattered by the layer 20 of scattering material. As discussed above, maximizing the distance 70 between light scattering events (e.g., hop distance λₕₒₚ) can increase the amount of light collected by the photosensitive device 40. Beneficially, the reflective surface 50 can be used to increase the hop distance (e.g., hop distance λₕₒₚ). One or more photosensitive devices, such as the photosensitive device 40, solar cells, or photovoltaic cells, on or in the reflective surface 50 can absorb and convert light energy into useful energy such as electricity.

For example, consider a light ray scattered to an angle of 45° relative to the layer 20 of scattering material, such as in Lambertian scattering, which generally scatters half of the incident light to angles greater than 45 degrees and half of the incident radiation to angles less than 45 degrees. As illustrated in FIG. 1, scattered at 45°, the lateral distance 70 that light 60 travels is approximately 2 d; where d is the thickness of the layer 30 of low-absorption medium. Therefore, the diffusion length of Equation 4 can be rewritten in terms of the thickness of the layer of low-absorption medium, as set forth in Equation 5 below:

$$𝓁 = \sqrt{\frac{1}{6} \frac{{λ}_{hop}}{α}} {\to }_{{λ}_{hop} = 2 d} \sqrt{\frac{1}{3} \frac{d}{α}} \qquad ( 5 )$$

Equation 5 illustrates the relationship between the thickness d of the layer 30 of low-absorption medium and the distance 70 light travels laterally within the layer of low-absorption medium. Generally, the lateral distance 70 that light travels within the layer 30 of low-absorption medium varies directly with the thickness d of the layer 30 of low-absorption medium. For example, reducing the thickness d of the layer 30 of low-absorption medium by a factor of 2 correspondingly reduces the diffusion length by approximately 29%. Additionally, the reflectivity of the reflective surface 50 contributes to the effective value of absorption (e.g., a poor reflecting mirror would markedly reduce the value of l in Equation 5).

In some embodiments, the lateral distance 70 that light travels laterally to the relatively small photosensitive devices 40, or an estimation thereof, affects some design considerations of the structure 10 or apparatus. Such considerations can include photosensitive device design, including the size of the photosensitive devices 40 and the spacing between the photosensitive devices (e.g., regions 245, described below). In some embodiments, the distance that radiation, such as light, travels laterally within the structure or apparatus 10 is determined and used to determine a spacing of photosensitive devices (e.g., regions 245).

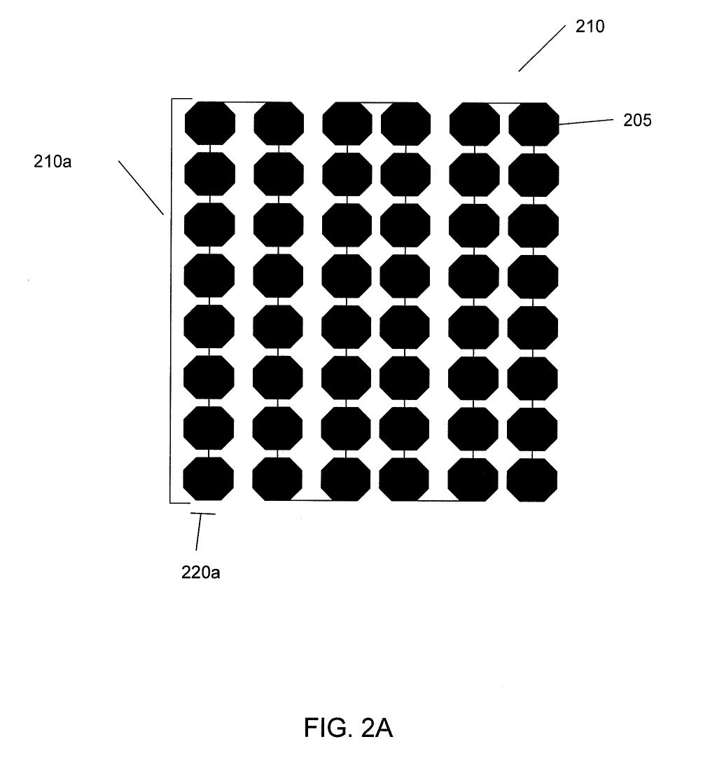

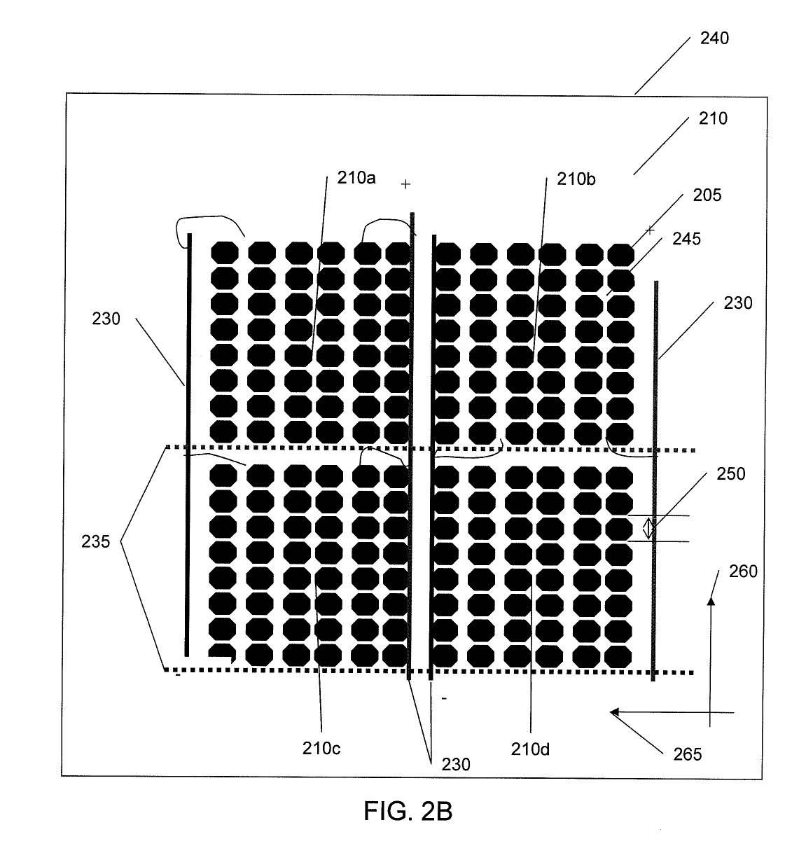

FIG. 2A depicts a portion 210a of a photosensitive device panel or module 210 illustrating electrical interconnection and/or intercommunication between photosensitive devices 205 on the panel or module 210. In some embodiments, the photosensitive devices 205 are electrically connected in series (e.g., as shown in array 220a) to form panels or modules, or portions thereof (e.g., the portion 210a). Arrays of photosensitive devices can also be connected in a parallel arrangement (not shown). FIG. 2B depicts a photosensitive device panel 210 including the portion 210a of a photosensitive device panel or module 210 of FIG. 2A in electrical communication with other portions 210b-210d of panel or module 210 and electrical interconnections 280 and 290 between the portions 210a-210d of panels or modules. In some embodiments, the portion 210a of panel or module 210 can be electrically connected in parallel to the portions 210b-210d of panels or modules, illustrated with electrical connections 230 and 235. To provide increased resiliency from damage to one or more of the portions 210a-210d of the panel or module 210, the portions 210a-210d of panel or module 210 can be connected with one or more redundant vertical buses 230 and/or horizontal buses 235.

In some embodiments, portions or regions of the panel or module 210 can be functionally isolated. For example, when one portion (e.g., 210a) or region of the panel or module 210 is sufficiently damaged to the extent that the portion (e.g., 210a) or region can no longer produce useable or functional panel voltage, the portion or region (e.g., 210a) ceases to contribute to the overall current that the panel 210 generates. The reduction in power is proportional to the ratio of the size of the portion (e.g., 210a) or region relative to the size of the full panel 210. In some applications of panels or modules where damage is expected, blocking diodes (not shown) can be used with each portion or region (e.g., portions 210a-210d) to prevent a damaged portion (e.g., 210a) or region from short-circuiting the entire panel 210. A given portion or region and/or group of portions or regions can be prevented from discharging the entire panel by scaling wire leads (not shown) and/or bus bars (not shown) that act as fuses.

In some embodiments, the panel or module 210 can be backed and/or faced by thin polymer or polymer-based materials, such as Mylar® films, illustrated by the outline which is shown as box 240. These films can also facilitate collection and conveyance of light from the regions 245 between photosensitive devices to the photosensitive devices.

Several advantages are realized by the panel 10 of FIG. 2B. For example, the panel or module 210 and photosensitive devices 205 provide for effective collection of light from the regions 245 between photosensitive devices 205, making larger regions 245 between photosensitive devices 205 and, therefore, greater mechanical flexibility of the panel or module 210 possible. Flexibility and damage resistance are generally related to the diameter 250 of the photosensitive devices 205 included in or on the panel or module 210, such as solar cells or thermal photovoltaic cells. In general, smaller photosensitive devices 205 exhibit increased resistance to damage and/or enable greater panel 210 flexibility. For example, in an embodiment in which photosensitive devices 205 are arranged in a two-dimensional, square array (e.g., as illustrated by panel 210), at least two orthogonal rolling axes 260 and 265 are provided.

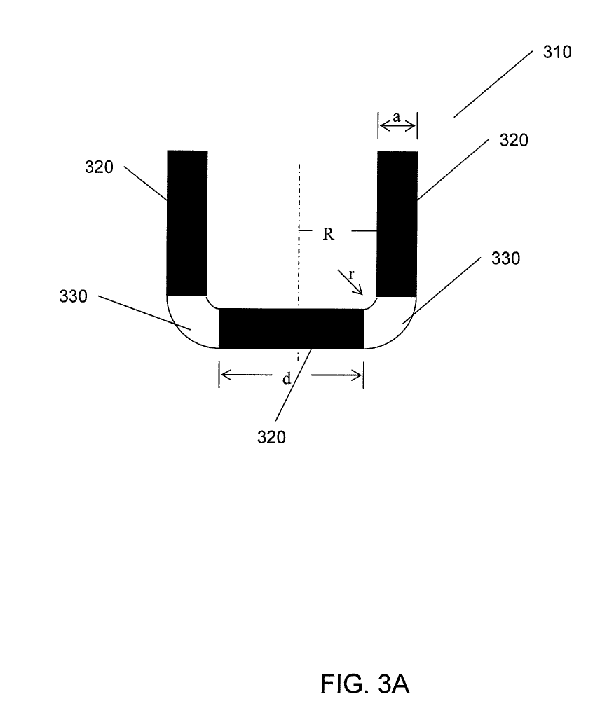

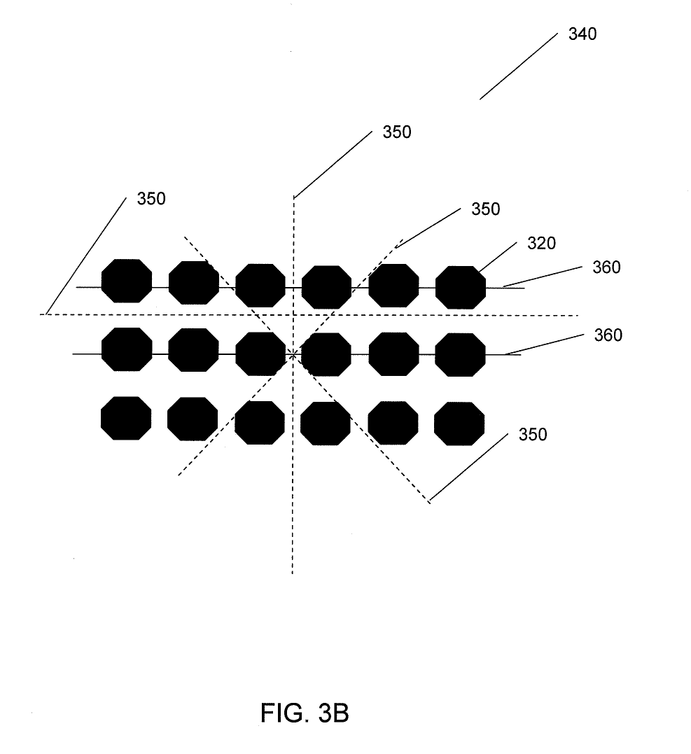

FIG. 3A depicts a cross-sectional view of a panel or module 310 in a flexed arrangement. The panel or module 310 includes one or more photosensitive devices 320 and a structure 330 (e.g., the structure 10 of FIG. 1). The radius of curvature, R, of the panel or module 310 is described in Equation 6, in which d is the photosensitive device diameter, r is the radius through which the panel or module is bent, and a is the thickness of the photosensitive device:

R=d/2+r+a (6)

The minimum value of the bending radius r is zero, and therefore, the minimum panel radius, R, of curvature is represented as R=d/2+a.

FIG. 3B depicts a photosensitive device panel or module 340 and illustrates the panel's or module's folding axes 350. In embodiments in which the photosensitive devices 320 define an octagonal shape, photosensitive device 320 corner relief can provide additional folding axes 350 and can also reduce the chance that a stress or strain acting on the panel or module 340 will break off a corner of a photosensitive device 320. In some embodiments, flexible wire connections 360 facilitate electrical communication between photosensitive devices 320 within or on the panel or module 340. The wire connections 360 that interconnect photosensitive devices 320 can be sufficiently relieved so as to permit bending. In such embodiments, the intrinsic bending dynamics of the panels or modules 340 relate to that of the flexible films (e.g., film 295), layers (e.g., layers 20 and 30), structures (e.g., structure 10), or media forming the regions between the photosensitive devices (e.g. layers 20 and 30) or photosensitive device sites.

### Thermal Photovoltaic Embodiment

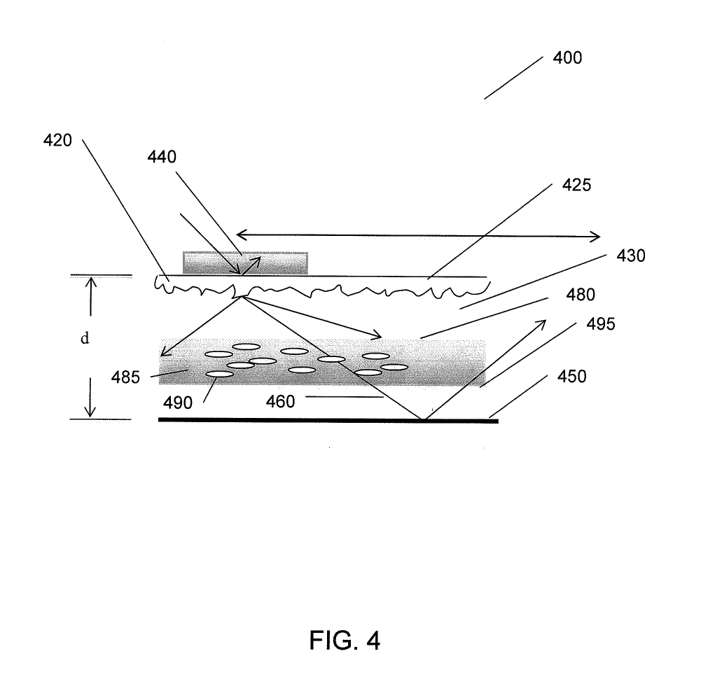

In solar cell applications, for example where the photosensitive devices are solar cells that convert light in the visible spectrum into useable energy, the structure 10 described with reference to FIG. 1 transports or delivers light to or facilitates the light reaching solar cells via a low-absorption medium (e.g., layers 20 and 30). The concepts described herein are also applicable to applications using thermal photovoltaic cells, which convert radiation in the infrared spectrum (e.g., heat) to useable energy. FIG. 4 depicts a cross-sectional view of a structure or device 400 that includes a layer 420 of scattering material, a thermal photovoltaic solar cell 440 over the layer 420 of scattering material, a layer 430 of low-absorption medium, a reflective surface 450, and a spectral-modification structure 480 within the layer 430 of low-absorption medium. In some embodiments, the thermal photovoltaic cell 440 is positioned over, on, or above the radiation-incident side 425 of the layer 420 of scattering material. Radiation 460 that is not absorbed in the thermal photovoltaic cell 440 or scattered by the layer 420 of scattering material passes into the layer 430 of low-absorption medium for modification by the spectral-modification structure 480. Radiation 460 is then reflected at the reflective surface 450 or absorbed by other thermal photovoltaic cells, such as crystal germanium based cells, or solar cells (not shown) in or below the layer 430 of low-absorption medium. This embodiment utilizes the structure 480 to lengthen the optical path in the transparent, low-absorption medium.

Apparatus and structures 400 can also be designed and constructed to modify the spectrum of light or radiation that emerges after passing through the thermal photovoltaic cell 440 to produce or generate radiation having a broader spectrum, such as a spectrum containing increased energy to be converted to electricity. In such an embodiment, modifying the spectrum of incident light to include a greater portion of light with energy greater than the band-gap of, for example, a solar cell (not shown) allows greater power generation.

In some embodiments, spectral modification structure 480 can facilitate a Stokes-type or anti-Stokes-type modification of incident radiation in or on the layer 430 of low-absorption medium. For example, in an embodiment not shown, the spectral modification structure 480 can include a structure that is used to increase the probability of a Raman scattering up- or down-conversion process, such as structures previously described in U.S. patent application Ser. No. 12/175,208, titled “Solar Cell,” and filed Jul. 17, 2008 by Fortmann, the entire contents of which are hereby incorporated by reference. A Raman scattering material can include, for example, crystal silicon nano-particles. The use of Raman-scattering materials lengthens the path-length over which light having a wavelength less than the band-gap of a solar cell can pass before being absorbed. Changing the path-length facilitates up-and-down spectral conversion of light, which, in turn, leads to improved thermal photovoltaic cell performance.

For example, U.S. patent application Ser. No. 12/175,208 describes a Raman scattering structure including a composite film of approximately micron-size crystalline silicon particles embedded in a conductive, amorphous silicon-carbide film. The composite film can be disposed on the bottom of and optically-coupled to an amorphous silicon solar cell. In this exemplary structure, the micron-size silicon particles up and/or down-convert incident long wavelength light via Raman Scattering. In other exemplary structures described by U.S. patent application Ser. No. 12/175,208, structures can include luminescent elements to provide spectral down-conversion of high-energy light. The luminescent elements can include particles of yttrium, erbium, rhenium, hafnium, or any other commercially available phosphors. The particles can be bound using any suitable material, such as glass or transparent plastics particles melted for binding the elements together.

In some embodiments, the spectral modification structure 480 can include a substantially-transparent medium forming a matrix 485 with particles 490 embedded in medium 485. The matrix 485 can be made from a silicon-carbide film. The particles 490 can, for example, be made from a luminescent material, a silicon material, a Raman-shifting particle, or any combination of these. The spectral modification structure 480 can also include a second matrix 495 having a different refractive index than the first matrix 485. The matrix 495 with the second refractive index can be positioned adjacent to the substantially-transparent matrix 485 with the first refractive index.

### Additional Photovoltaic Embodiments

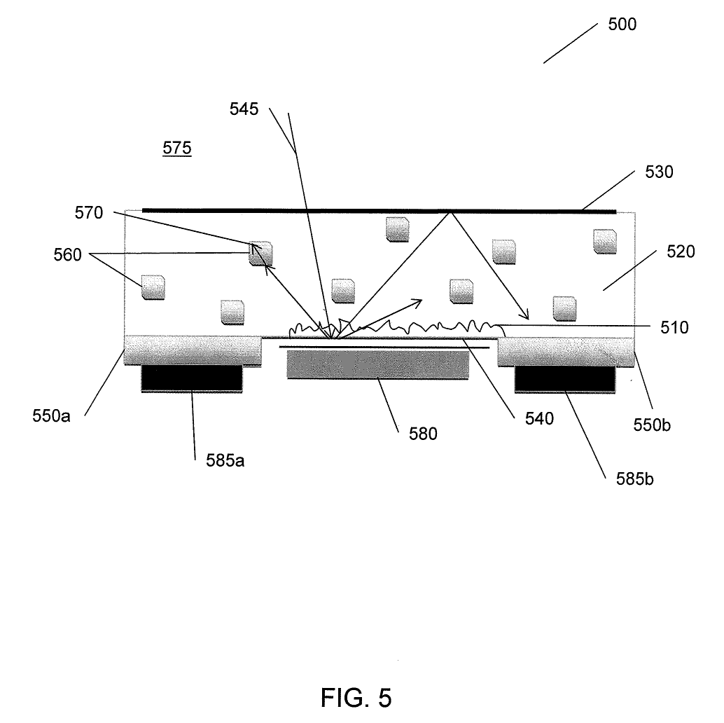

FIG. 5 depicts a cross-sectional view of a structure or device 500 that includes a layer 510 of scattering material, a layer 520 of low-absorption medium having a smooth surface 530, a reflective surface 540, photovoltaic cells 550a-550b and a thermal regulation unit 580. The device 500 also includes thermal regulation units 585a-585b that are in thermal communication with the photovoltaic cells 550a-550b. In some embodiments, the thermal regulation unit 580 and the thermal regulation units 585a-585b form a thermal regulation system. Either thermal regulation unit 580 or thermal regulation units 585a-585b (alone or in combination) can also form a thermal regulation system. The layer 510 of scattering material can be partially or fully integrated into the structure or device 500. For example, the layer 510 of scattering material can be partially or fully incorporated into the layer 520 of low-absorption medium. For example, the layer 510 can be formed in the process used to form the layer 520 of low-absorption medium. In some embodiments, the layer 510 of scattering material is partially or fully incorporated into the reflective surface 540 (e.g., formed in the process used to form the reflective surface 540 or physically or thermally bonded to the reflective surface 540). Some embodiments feature the layer 510 of scattering material being incorporated both into the layer 520 of low-absorption medium and incorporated into the reflective surface 540. The layer 510 of scattering material can be disposed between the layer 520 of low-absorption medium and the reflective surface 540 but not physically connected, bonded or coupled to either the layer 520 or the reflective surface 540. A benefit of disposing the layer 510 of scattering material in and/or between the layer 520 of low-absorption medium and the reflective surface 540 is reduction of scattering of incident radiation 545 (e.g., light or heat) away from or out of the structure or device 500 before the incident radiation 545 reaches the photovoltaic cells 550 for conversion into electrical power. Additionally, anti-reflection coatings (not shown) can be deposited on or applied to the smooth surface 530 to reduce reflection of the radiation 545.

The layer 520 of low-absorption medium can include a spectral-modification material or media 560, such as a Raman-scattering media. The spectral-modification media 560 can be evenly distributed throughout the layer 520 of low-absorption medium. In some embodiments, the spectral-modification material 560 is distributed throughout the layer 520 according to a predetermined criterion or to achieve a desired performance of the device 500. The spectral-modification media 560 can be disposed over or within a portion (not shown) of the layer 520 of low-absorption medium. In some embodiments, the layer 520 of low-absorption medium and the spectral-modification media 560 have differing refractive indexes. For example, the spectral-modification media 560 can have a relatively large refractive index, e.g., 1.5, compared to that of the layer 520 of low-absorption medium, e.g., 1. Other values of the indices of refraction can be used, depending on the particular application or a desired characteristic of the device 500. The different refractive indexes can affect the length of a radiation path 570 within the spectral-modification material media 560 (e.g., by increasing the path 570 to promote absorption or spectral modification) and, therefore, increasing the probability that incident radiation 545 is, for example, Raman scattered and/or shifted. Similarly, reducing the path 570 can promote transmission of radiation or spectral modification by a differing amount.

In embodiments where the spectral-modification media 560 includes Raman-scattering media or materials, the spectral-modification media 560 can be heated relative to the temperature of the ambient environment 575 of the structure or device 500 and/or relative to the temperature of the photovoltaic cells 550a-550b to increase the probability of Raman up-scattering events. The thermal regulation unit 580 can use any technique to heat the spectral-modification media 560, such as using electric heating and/or supplying heat obtained from an illumination source (not shown). Additional heating techniques (e.g., conductive, convective, or radiative heating) may also be used, depending on the particular application or heat requirements (or heat flux requirements). The thermal regulation system can, in some embodiments, feature an electrical and/or thermal feedback loop or control system or structure to facilitate setting or regulating a temperature of system components. Raman up-scattering events generally increase the average energy of radiation within the incident radiation's 545 spectrum. Small-sized spectral-modification materials 560, such as Raman-scattering media, can be employed to increase the probability of Raman up-conversion.

In embodiments where the photovoltaic cells 550a-550b convert spectral energy more efficiently at relatively lower incident radiation energies, the spectral-modification material 560 can be cooled relative to the temperature of the ambient environment 575 of the structure or device 500 and/or relative to the temperature of the photovoltaic cells 550a-550b to, for example, increase the probability of Raman down-scattering events. The thermal regulation unit 580 can use any suitable technique to cool the spectral-modification media 560, such as conductive, convective or radiative cooling. In a conductive cooling embodiment, a fluid (e.g., liquid or air) cooling system (not shown) can be used. Suitable liquids include, for example, water, Freon, or other commercially or generally-available coolants.

The temperature of photovoltaic cells 550a-550b can also be regulated (e.g., adjusted or controlled). For example, where radiation 545 incident upon the photovoltaic cells 550a-550b increases the temperature of photovoltaic cells 550a-550b above a pre-determined operating range, the thermal regulation units 585a-585b can be used to cool the photovoltaic cells 550a-550b to below the predetermined operating range and/or to a desired temperature relative to the temperature of the ambient environment 575 or other parts of the structure 500, such as the layer 520 of low-absorption medium or the spectral-modification media 560.

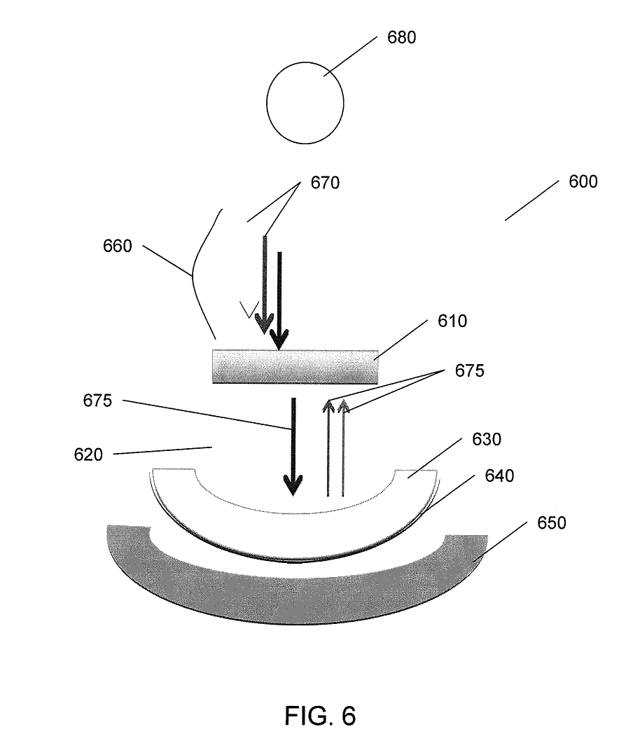

FIG. 6 depicts a cross-sectional view of a structure or device 600 that includes a photovoltaic cell 610, a layer 620 of low-absorption medium, Raman-scattering material or media 630, a reflective surface 640, and a thermal regulation unit 650. The photovoltaic cell 610 can be a solar photovoltaic cell or a thermal photovoltaic cell. In some embodiments, incident radiation 660 includes a radiation spectrum (e.g., either narrow-band or broad-band, depending on the particular application). A portion 670 of the incident radiation 660 band can be absorbed by the photovoltaic cell 610 and a portion 675 of the incident radiation 660 band can pass through photovoltaic cell 610 without being absorbed. The portion 675 of the incident radiation 660 that passes through the photovoltaic cell 610 without being absorbed can then be Raman-scattered (e.g., converted up or down) at or within the Raman scattering media 630 and/or reflected by the reflective surface 640 toward the photovoltaic cell 610 for absorption by the photovoltaic cell 610. In this way, radiation that is not absorbed in the photovoltaic cell 610 on a first pass therethrough and has gained sufficient energy through Raman scattering can be collected and/or absorbed on a second or subsequent pass through the photovoltaic cell 610.

In some embodiments, disposing the layer 620 of low-absorption medium between the photovoltaic cell 610 and the Raman scattering media 630 beneficially facilitates achievement or maintenance of different temperatures for the photovoltaic cell 610 and the Raman-scattering material or media 630. For example, in embodiments where the photovoltaic cell 610 is a thermal photovoltaic cell, a heat source 680 that provides incident radiation 660 can also be used to increase the temperature of or heat the Raman-scattering media 630. A thermal regulation unit 650, in thermal communication with the Raman-scattering media 630, can regulate the temperature of the Raman-scattering media 630, e.g., using cooling techniques.

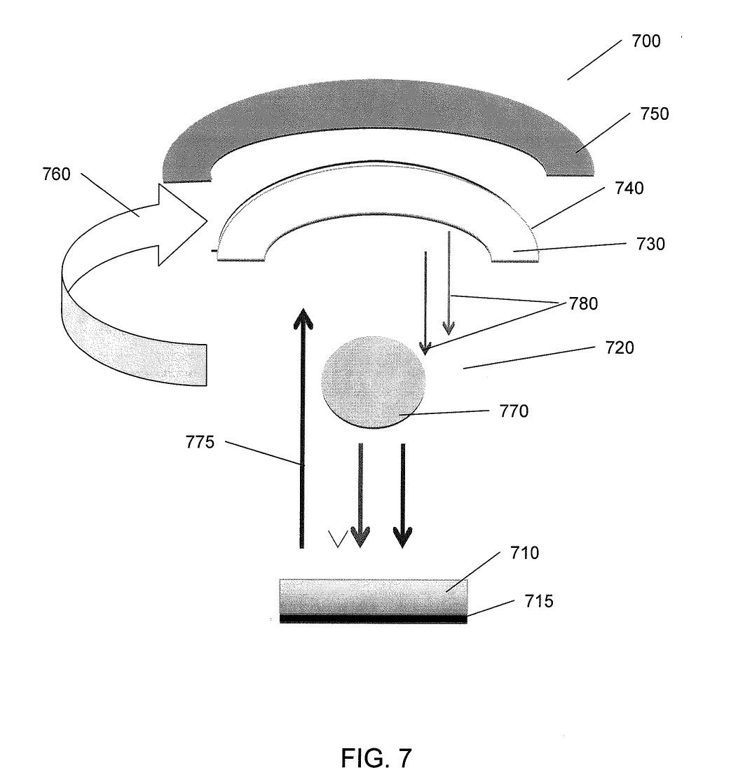

FIG. 7 depicts a cross-sectional view of a structure or device 700 that includes a photovoltaic cell 710, a first reflective surface 715, a layer 720 of low-absorption medium, a Raman-scattering material or media 730, a second reflective surface 740, a thermal regulation unit 750, and a thermal conduit 760. In some embodiments, Raman-scattering material or media can also include scattering material (not shown). A radiation source 770 provides radiation to the structure or device 700. In some embodiments, the photovoltaic cell 710 absorbs some of the incident radiation and permits some radiation to pass therethrough. Some radiation may also be reflected. The layer 720 of low-absorption medium, the Raman scattering media 730, and the second reflective surface 740 are disposed to receive radiation 775 that reflects from the photovoltaic cell 710 and/or passes through the photovoltaic cell 710. In a detailed embodiment, some incident radiation is reflected at the first reflective surface 715 of the photovoltaic cell 710 and/or passes out of the photovoltaic cell 710. Incident radiation 775 can also be reflected by backing (not shown) on the photovoltaic cell 710. The layer 720 of low-absorption medium, the Raman-scattering media 730, and the second reflective surface 740 can then focus collected radiation 780 onto the photovoltaic cell 710. In some embodiments, the layer 720 of low-absorption medium, the Raman scattering media 730, and the second reflective surface 740 are also positioned to receive radiation (not shown) from radiation source 770 and reflect and/or concentrate the radiation (not shown) toward photovoltaic cell 710. For example, the layer 720, media 730, and reflective surface 740 can form a mirror-like structure having a concave geometry such as, for example, a circular, parabolic, elliptical, or hyperbolic geometry.

The structure or device 700 can also use the thermal regulation unit 750 to control, set or regulate a temperature of the Raman scattering media 730, for example, by maintaining the Raman scattering media 730 at a specific temperature (e.g., in an electrical or thermal control loop or feedback loop). In some embodiments, optical and/or thermal regulation of the Raman scattering media 730 can also use heat transferred by the conduit 760. The conduit 760 can be in thermal communication with radiation source 770 and/or with a heat source that is also acts as a source of radiation for the photovoltaic cell (not shown).

### Dye-Based Light Scattering Material Layer Embodiment

In some embodiments photosensitive devices 40 include dye-type solar cells able to reach efficiencies of about 10%. Such embodiments involve a thin film of dye (not shown), for example, a few mono-layers when averaged over the entire solar cell area, receiving about 10 or more light passes. In these embodiments, the dye-type solar cell can be disposed between two TiO₂-based layers.

### Light Scattering Material Design

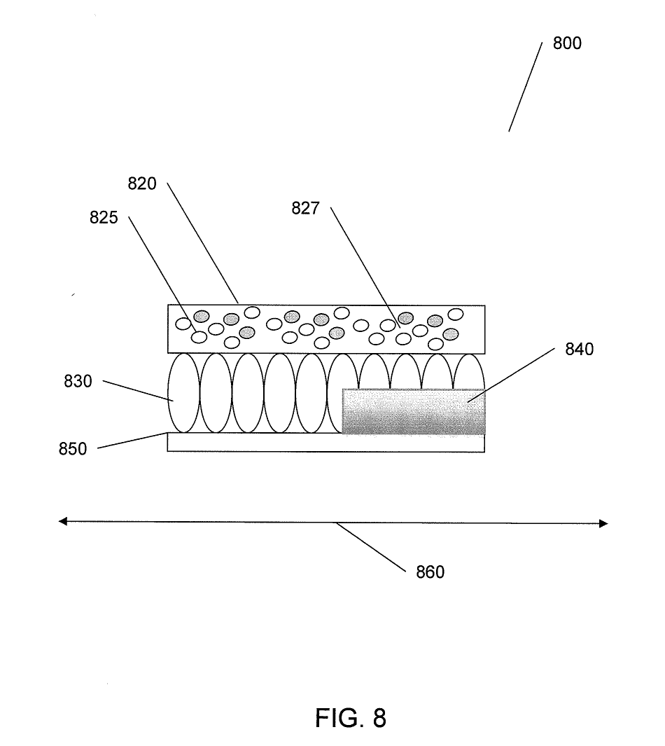

FIG. 8 depicts a cross-sectional view of a structure or device 800 that includes a layer 820 of scattering material containing small-grained materials or media 825, a layer 830 of low-absorption medium, a reflective surface 850, and a photosensitive device 840. The layer 820 of light scattering material can include many small-grained, non-light-absorbing materials 825 or media such as, for example, rough glass, and/or small crystallites disposed on or within the layer 830 of low-absorption media. For example, TiO₂ layers can be deposited onto glass to create the layer 820 of light scattering material. The color and/or texture of the layer 820 of light scattering material can be engineered by mixing together two or more small-grained materials, for example, TiO₂ and alumina. Additionally, mixing appropriate sized TiO₂ particles with lower-refractive-index particles, such as glass or alumina, produces an inexpensive, random photonic crystal. By controlling the ratio of high-index TiO₂ particles to low-index particles in the layer 820 of scattering material, the average spacing 827 between nearest-neighbor, low-index particles can be determined. In-turn, this inter-particle spacing 827 affects or determines the wavelengths of incident radiation to be reflected. For example, the approximate wavelength of reflected radiation, λ, is given by Equation 7, where η is the refractive index of the TiO₂ matrix, and rₐᵥₑ is the average spacing of the low-index particles:

λ≈ηrₐᵥₑ/2 (7)

Moreover, the layer 820 of scattering material can facilitate spectral scattering of the incident radiation. In some embodiments, photonic-engineered materials 825 of the layer 820 of scattering material can be used to selectively reject un-convertible portions of the illumination spectrum, such as long wavelength light, to prevent photosensitive devices 840 heating. Photonic-engineered TiO₂ particles 825 can also be used in applications where camouflage is more important than panel or module efficiency.

Additionally, in some embodiments, the layer 830 of low-absorption medium can include air/polymer spacers (akin to a low-absorption “bubble-wrap” structure) for applications where thicker structures can be tolerated. As explained in further detail above, as the thickness of the layer 830 of low-absorption medium increases, light diffuses further (e.g., back or forth along the axis indicated by line 80). A relatively thicker layer 830 of low-absorption medium reduces the area of the panel or module that needs to be devoted to photosensitive devices 840 and/or photosensitive device sites (shown occupied by photosensitive devices 840) without materially sacrificing power generation by the panel or module (e.g., panel or module 210). The simple nature of the structure 800 permits the structure 800 to be tailored to fit specific applications without extreme customization costs.

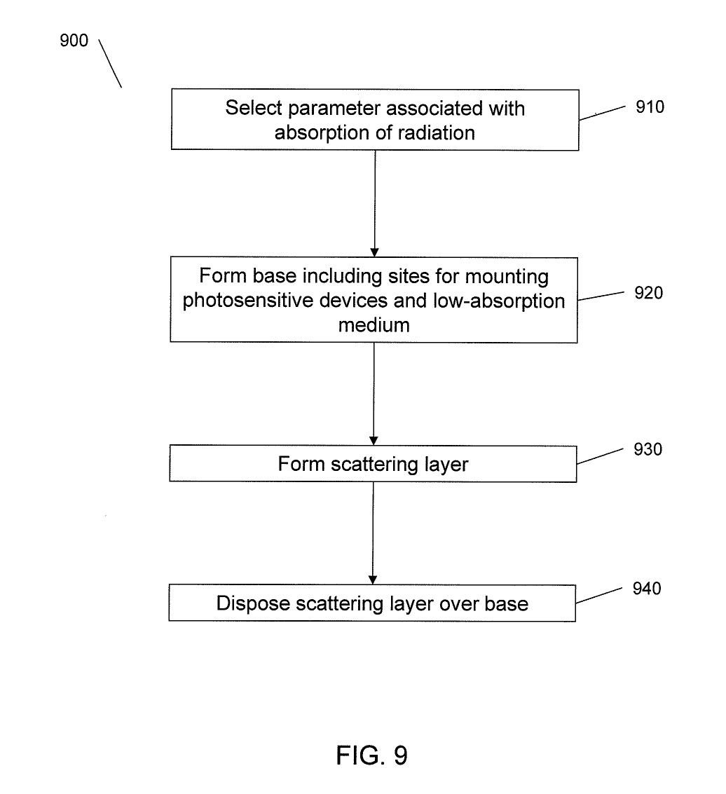

Some embodiments feature a method. FIG. 9 is a flow chart 900 that depicts a method of assembling a panel or module. Step 910 involves selecting a parameter associated with the absorption of radiation. For example, the parameter can be the desired absorption coefficient of a medium or combination of media used to assemble a panel or module as used in, e.g., Equation 5 to estimate the diffusion length in the medium or media.

In step 920, a flexible base is formed. The base can include a plurality of sites for mounting photosensitive devices. The base can also include a medium disposed in between the sites for mounting photosensitive devices. The size of the spaces between the sites for mounting photosensitive devices can be based, in part, on the parameter selected in step 910. For example, as discussed above, the distance that radiation travels laterally within the medium disposed between the sites for mounting photosensitive devices can be determined, in part, based on the absorption coefficient of the medium. The distance radiation travels laterally within the medium can then be used to determine a spacing of sites for mounting photosensitive devices. For example, sites for mounting photosensitive devices can be located such that the distance between neighboring sites is no greater than the distance radiation travels laterally within the medium, as determined by Equation 5 or a predetermined fraction thereof.

In step 930, a scattering layer is formed. The scattering layer can be formed from polymer-based materials, a crystalline or polycrystalline material, a structured surface, a granular organic material, a granular inorganic material, or any combination of thereof. The polymer-based materials can include, for example, titanium oxide, titanium dioxide, zinc oxide, cadmium sulfide, glass particles, plastic based particles, or any combination of these. In some embodiments, the scattering layer is formed by applying a coating in or on the flexible base. Exemplary processes for forming a scattering layer include screen printing, spraying, or vacuum deposition. The scattering layer can also be formed as described with respect to any other embodiment described herein.

Additionally, formation of the scattering layer can be based, in part, on a parameter associated with the scattering of incident radiation, such as the scattering angle of light incident upon the scattering layer or a desired angle of refraction for the scattering layer. In other embodiments, the parameter associated with the scattering of incident radiation can be the desired wavelength or range of wavelengths of incident radiation to be reflected by the scattering layer. In step 940, the scattering layer is disposed over a base, e.g., a flexible base.

### Exemplary Applications

The color and/or texture of structures or devices can be tailored to a large range of panel or module designs depending on the desired application. For example, for applications incorporating a module into garments, ventilation holes can be provided and/or Gore-Tex® like backing material can be used, for example, as a support structure between the photosensitive devices. Photosensitive device density, the space between photosensitive devices, and product smoothness can be varied to optimize comfort, off-normal-light-angle conversion efficiency, and weight for specific power density under normally incident light.

As previously discussed, in some applications, spectral tuning of light collection can be achieved by mixing materials, e.g., materials 825, with different refractive indexes into the layer of scattering material, e.g., layer 820, to create a random photonic crystal with the ability to partially reject a part of the solar spectrum. These photonic-engineered systems permit even finer tailoring for a degree of terrain color matching and for optical tuning for extreme solar irradiance environments.

In some embodiments, the scattering layer, e.g., layer 820, can include photonic-engineered TiO₂ materials, e.g., materials 825, selected to selectively reject infrared radiation, thereby reducing heating of the photosensitive devices 840 and the panel or module, e.g., panel or module 210. Reduced heating of the photosensitive devices 840 and the panel or module, e.g., panel or module 210, thereby decreases the infrared signature of the panel or module, e.g., panel or module 210, and, possibly, a wearer in field deployments (not shown).

Panels or modules, e.g., panel or module 210, are also potentially useful for unmanned aircraft, for example, to provide mission-extending power, alternative communication, and/or environmental sensing. In some embodiments, use of materials with relatively large refractive indexes, such as silicon spheres and TiO₂ materials, in the scattering layer maximize use of off-normal incident light. Additionally, since the photosensitive devices are packaged in a panel or module, e.g., panel or module 210, rather than monolithically deposited, as is typical of thin film solar cells, a space between silicon spheres or under a silicon sphere in a given region can be dedicated to a particular function, such as a power and/or position-code generator. Multiple regions can be used together to enable the entire panel to be used as an imaging device capable of sensing nearby aircraft, clouds, sun position, as well as to be used to receive near-infrared signals from aircraft and space craft. In such embodiments, a smooth polymer layer can be used to smooth airflow over aircraft surfaces on which a panel or module, e.g., panel or module 210, is disposed.

Panels or modules, e.g., panel or module 210, can be used for mobile electric power generation. For example, a solar electric vest can be fashioned with fibers aligned for maximum power-to-weight ratio and/or with a small amount of the space between silicon spheres dedicated to ventilation holes for wearer comfort. The vest could be used, for example, to power cell phones, global positioning system (GPS) receivers, toxic hazard detectors and/or other equipment. Since the solar cell panel or module operates as a series of small, thread-like solar cells, bullet holes and other damage would deactivate the region directly affected. As previously discussed, the panel can be designed to segregate functions or regions of the panel such that a failure of one function or in one region does not significantly impact other functions or regions.

Other exemplary applications include use of flexible panels or modules as tent-roofs and/or stand-alone solar mats, which can be placed on the ground for reduced optical signature. Panels or modules can also be used and/or placed on foldable stands or structures at an optimal solar irradiance angle to generate sufficient energy to run an encampment. Rough surfaces where the light conveyance media between spherical solar cells is thinner than the sphere radius can also be used to enhance transport and/or collection of non-normal incident light.

In embodiments in which the scattering material includes TiO₂, photonic-engineered TiO₂ materials provide the ability to vary the color of the panel or module with a relatively small loss in efficiency for applications in which visually camouflaging the panel is desired. In some embodiments, the panel or module can be rigid (e.g., for use as a relatively permanent installation). The panels or modules can also be used to design and/or construct arrays of thermal photovoltaic solar cells and/or generators.

### Platform Efficiency Projection

In some embodiments, the photosensitive devices can be high-efficiency, single-crystal silicon solar cells. Solar cells that are fabricated using high-quality, long-lifetime crystalline silicon, such as SunPower® Solar Cells, have approximately 20% efficiency under highly concentrated sunlight. Beneficially, a panel or module in which approximately 50% of the surface area consists of solar cells permits flexibility in design, providing a comfortable margin for optimizing the performance of panel or module with and without space between the solar cells.

In some embodiments, up to approximately 50% of the light incident on the solar cell panel or module is incident on spaces between solar cells in the panel or module. Up to approximately 80% of the light incident on spaces between solar cells can be transported to the solar cells in the panel or module. Assuming 20% efficiency for the 50% of the light falling on the solar cells and 20% efficiency for the 80% of incident radiation on spaces between solar cells (e.g., 0.8×20%=16%), the average efficiency for the panel or module is 18% efficiency. In some embodiments, utilizing a reflective surface that reflects more than 90% of radiation adjacent to the low-absorption medium and reflection from the scattering material (e.g., thin, optimized TiO₂ light scattering layer) can lead to collecting approximately 90% of the light incident on spaces between solar cells.

Experimental testing has confirmed the efficiency findings described above. Using a collector, further described below, employing un-optimized TiO₂-based coatings and an un-optimized glass mirror, an experiment at the State University of New York—Stony Brook confirmed light conveyance from the non-active regions surrounding a small solar cell is possible. The power produced by an approximately 0.5 cm² (e.g., approximately 0.7 cm on each edge) silicon solar cell was increased by approximately 20% when a structure, as described herein, was used to collect and transport light to the solar cell. The result is consistent with the structures extending the efficient collection of light by approximately 0.07 cm beyond the edge of the solar cell. Extrapolating, this result indicates that a panel or module in which solar cells are spaced approximately 0.14 cm apart would perform on-par with a larger, one-piece solar cell.

While the apparatus, structures, and methods have been particularly shown and described with reference to specific embodiments, it should be understood by those skilled in the art that various changes in form and detail may be made therein without departing from the spirit and scope of defined by the appended claims.

What is claimed is:

1. An apparatus comprising:
a low-absorption medium capable of passing and absorbing incident radiation;
a scattering material disposed over at least a portion of or within the low-absorption material, the scattering material pen fitting a portion of incident light to pass therethrough; and
a reflective surface disposed adjacent the low-absorption medium to reflect radiation towards or within the medium.

2. The apparatus of claim 1, wherein the scattering material comprises at least one of a polymer-based material, a crystalline or polycrystalline material, a structured surface, a granular organic material, a granular inorganic material, or any combination thereof.

3. The apparatus of claim 2, wherein the polymer-based material comprises at least one of titanium oxide, zinc oxide, cadmium sulfide, glass particles, plastic-based materials, or any combination thereof.

4. The apparatus of claim 1, wherein the low-absorption medium comprises at least one of air, a polymer material, a glass material, water-based materials, quartz, diamond, or any combination thereof.

5. The apparatus of claim 1, wherein the low-absorption medium comprises a material substantially transparent to radiation within a range of operation of an optically-coupled photosensitive device within or on the apparatus.

6. The apparatus of claim 1, wherein the low-absorption medium defines an array of sites at which photosensitive or photovoltaic devices are located and spaces between the sites.

7. The apparatus of claim 1, further comprising a spectral-conversion structure that facilitates a Stokes-type or anti-Stokes-type modification of incident radiation in or on the medium.

8. The apparatus of claim 7, wherein the spectral conversion structure comprises:
a substantially-transparent matrix having particles embedded therein and a first refractive index, the particles including at least one of a luminescent material, a silicon material, a Raman-shifting particle, or any combination thereof.

9. The apparatus of claim 8, further comprising a matrix with a second refractive index substantially different than the first refractive index.

10. The apparatus of claim 8, wherein the matrix comprising a silicon-carbide film.

11. The apparatus of claim 8, further comprising a thermal photovoltaic solar cell.

12. The apparatus of claim 11, wherein the thermal photovoltaic solar cell is supported on the scattering material to permit incident light to be either absorbed in the thermal photovoltaic solar cell or passed to the spectral-conversion structure for modification and subsequent absorption.

13. The apparatus of claim 1, further comprising a photosensitive device or a photovoltaic device disposed within or over the medium.

14. The apparatus of claim 13, wherein the photosensitive device is a silicon-based solar cell or the photovoltaic device is a thermal photovoltaic cell.

15. The apparatus of claim 1, wherein the scattering material comprises:
a first layer including titanium oxide;
a second layer including titanium oxide; and
an intermediate layer comprising a dye material disposed between the first and second layers.

16. The apparatus of claim 1, wherein the reflective surface comprises at least one of a metallic material, a dielectric coating, a mirror, a half-wavelength coating, or any combination thereof.

17. The apparatus of claim 1, wherein the reflective surface comprises a reflection-enhancing material or coating.

18. A solar cell module comprising:
a flexible base having a plurality of photosensitive devices mounted thereon or thereto, the flexible base comprising a low-absorption medium disposed at least between the plurality of photosensitive devices, the medium permitting radiation to pass to the plurality of photosensitive devices, at least one of the plurality of photosensitive devices in electrical communication with at least one other photosensitive device of the plurality of photosensitive devices; and
a scattering material disposed over the flexible base permitting a portion of incident radiation to pass therethrough to the plurality of photosensitive devices and the medium.

19. The module of claim 18, wherein the scattering material selectively rejects a portion of incident infrared radiation from passing to the plurality of photosensitive devices and the medium.

20. The module of claim 18, wherein the scattering material is a coating.

21. The module of claim 18, wherein at least one flexible interconnection facilitates electrical communication between the photosensitive devices of the plurality of photosensitive devices.

22. The module of claim 18, further comprising an electrical connection facilitating electrical communication between the module and a second module containing a second set of photosensitive devices.

23. The module of claim 18, wherein the module includes a first region associated with a first function and a second region associated with a second function.

24. The module of claim 23, wherein a condition in the first region of the module affecting the first function does not affect the second function.

25. A method comprising:
selecting a first parameter associated with absorption of incident light;
forming a flexible base that includes a plurality of sites each for mounting a photosensitive device and a medium disposed between the plurality of sites, the size of spaces between the plurality of sites being based on the selected first parameter;
forming a scattering layer based in part on a second parameter associated with scattering of incident radiation; and
disposing the scattering layer over the flexible base.

26. The method of claim 25, further comprising:
positioning a reflective surface of a film adjacent the flexible base.

27. The method of claim 26, further comprising forming the film, wherein forming the film includes depositing particles of a light-reflective material within a polymer film.

28. The method of claim 25, wherein forming the scattering layer includes depositing titanium oxide particles within or on a polymer film.

29. The method of claim 25, wherein forming the scattering layer further comprises:
forming a first layer including titanium oxide particles;
forming a second layer including titanium oxide particles; and
disposing an intermediate, dye-based layer between the first and second layers.

30. The method of claim 25, further comprising:
locating at least one photosensitive device at a site of the plurality of sites.

31. The method of claim 30, further comprising:
locating a second photosensitive device at a second site of the plurality of sites; and
connecting the photosensitive device and the second photosensitive device to facilitate electrical communication.

32. The method of claim 25, further comprising:
forming a spectral-modification structure by
forming a substantially transparent matrix having a first refractive index;
embedding at least one of a luminescent material, a silicon material, a Raman-shifting material, or any combination thereof within the matrix; and
disposing the spectral-modification structure on or within the medium.

33. The method of claim 32, further comprising positioning the matrix relative to a silicon-based substrate having a second refractive index substantially different than the first refractive index.

34. The method of claim 25, further comprising:
locating at least one thermal photovoltaic cell at a site of the plurality of sites.
